(19) United States
(12) Patent Application Publication
(10) Pub. No.: US 2009/0110916 A1
(43) Pub. Date: Apr. 30, 2009

(54) Multi-Layered Product for Printed Circuit Boards, and a Process for Continuous Manufacture of Same

(76) Inventor: Valery Ostrovsky, Ariel (IL)

Correspondence Address: EDWARD LANGER;c/o SHIBOLETH YISRAELI ROBERTS ZISMAN & CO., 1 PENN PLAZA-SUITE 2527, NEW YORK, NY, 10119, US

(21) Appl. No.: 11/988,072

(22) PCT Filed: Jul. 3, 2006
(86) PCT No.: PCT/IL2006/000772

§ 371 Date: Dec. 9, 2008

Related U.S. Application Data
(60) Provisional application No. 60/695,864, filed on Jul. 5, 2005.

(51) Int. Cl. B32B 15/085; B29C 70/88; B32B 37/00; B32B 37/02; H05K 1/05

(52) U.S. Cl. 428/336; 156/246; 156/244.11; 156/89.12; 156/89.14; 156/182; 156/244.17; 428/461; 428/335; 428/339

(57) ABSTRACT

The invention provides a low energy loss, multi-layered polypropylene/metal foil product useful for further processing into printed circuit boards and antenna boards for microwave circuitry. A continuous process for manufacture of the product is described. The process comprises the steps of: providing metal foil; optionally, extrusion coating molten polypropylene upon said metal foil, to obtain a foil coated with a polypropylene foundation layer; casting a molten polypropylene tie-layer upon said metal foil or upon said coated metal foil; and laminating a polypropylene sheet on said tie layer. In the process, heat is applied to induce fusing of the layers of the multi-layered product.

### FIELD OF THE INVENTION

The present invention relates to a multi-layered product useful for manufacturing printed circuit boards and antenna boards for microwave circuitry, having low losses of energy, and to a method for producing the same.

### BACKGROUND OF THE INVENTION

Microwave circuit boards, are typically formed of two conductive metal foils, having a material between them which has a predetermined dielectric constant; this material is hereafter termed the “dielectric substrate”. The board is then etched, or solvent-treated, to remove specific areas of the conductive foil, to create a circuit pattern, whose shape depends on the intended use. U.S. Pat. No. 4,335,180 to Traut describes a microwave circuit board and a method for its production.

When electric currents of 1-80 GHz are propagated through transmission lines on such a printed circuit board (PCB hereinafter), part of the transmitted energy is lost due to dielectric losses in the surrounding material. Thus, the materials used to make the printed circuit board substrates, or antenna boards, for use with microwave circuitry in particular, have to be chosen carefully. If not, the circuitry will be prone to losses and the efficiency will be low.

Any material that is used for a printed circuit board has to be able to withstand soldering temperatures, as components are frequently soldered onto the board. Additionally, the conductor paths are generally formed by chemical etching thus removing unwanted conductor cladding. The dielectric material used as the substrate in a printed circuit board has to be able to withstand the etching and soldering processes.

Typical dielectric materials used to date for the microwave substrates include Teflon™-glass, polyester-glass, epoxy glass and pure Teflon™. Each of these dielectric materials suffers from a specific drawback, making each less than ideal.

In circuit boards having glass-impregnated plastics such as the polyester-glass material as the dielectric substrate, the concentration of polar pieces of the resin molecules and glass fiber resonate at high microwave frequencies cause considerable dissipation of energy. This effectively limits use of this substrate to the lower part of the microwave spectrum.

Teflon™-glass substrates are widely used across the microwave range due to their low dissipation factor. However they are expensive for a number of reasons. Teflon™ is itself expensive. The manufacturing involves a cyclic lamination process using hot presses; the yield of this process is low and Teflon™ is not ideal due to its polarity.

As an alternative, polyester is cheaper, but has a dissipation factor which is significantly larger than Teflon™, 0.003 at frequencies above 1 GHz and reaching up to 0.005 at 10 GHz. Polyester also has a significant dissipation factor (DF) fluctuation over temperatures within the range of 25° C. to 80° C. and this limits its applications.

Another material that can be considered for the dielectric substrate in a printed circuit board is polyethylene. A PCB laminate made of polyethylene is disclosed in U.S. Pat. No. 5,972,484, to Cohen, et al. Polyethylene has attractive dielectric properties but has a low melting point (135° C.), which is below the melting point of tin-lead solders. This means that it cannot be used in standard assembly processes. Furthermore polyethylene has a significant thermal expansion coefficient at elevated temperatures. In addition, polyethylene shrinks when cooled after heating above 60-70° C., which occurs, for example, after etching. When gluing polyethylene laminations, the high temperatures required for setting the glue can give rise to local softening of the polyethylene and cause it to creep, resulting in variations in the thickness of the dielectric material.

A further disadvantage of polyethylene is that heat absorbed by the polyethylene substrate when laminated with molten bonding materials causes high-tension strain between the foil and the plastic as a result of the existence of different thermal contraction rates of the various layers. After the copper is etched away, the tension may be released and, since the conducting surface does not shrink, the laminate will distort. This results in warping in those areas where the remaining copper (namely that which remains after etching) has the strength to resist shrinkage.

In addition, use of polyethylene requires use of bonding adhesive materials (such as modified epoxy, polyurethane, etc.) for the low temperature laminating procedure. These bonding adhesives tend to cause an increase in the dissipation factor of the resin system to 0.009 and above, even though the thickness of the adhesive layer tends to be only be 2 to 6 microns thick.

EP 1160077, by the inventor, describes a printed circuit board material made of conducting foil, bonded and laminated to cross-linked polyethylene.

Polypropylene would be even more advantageous than prior art dielectric materials, including that described in EP 1160077, since polypropylene has nearly as low energy losses as polyethylene and is low in cost. However, application of polypropylene to metal foil PCBs is not obvious, since when no adhesive is used, and molten polypropylene is poured or otherwise applied onto PCBs, it will easily peel off upon cooling. Adhesives such as modified epoxy, polyurethane, etc., may not be used, since they considerably increase the energy dissipation factor to over 0.02 even though the thickness of the adhesive layer is minimal (several microns).

Thus, the need exists for a microwave circuit board, having a novel dielectric material, which has a minimal energy loss, is inexpensive to produce, and does not require use of adhesive for its incorporation into a circuit board.

### SUMMARY OF THE INVENTION

The present invention discloses a product for use in manufacturing a printed circuit board, having a novel dielectric material, which grants it advantages over prior art PCB laminates. There is additionally disclosed a novel method of manufacture of the product, that allows polypropylene coating and lamination of metal foil, for production of PCBs for microwave circuitry. The resultant novel product is resistant to peeling and has greater energy efficiency during use, than prior art PCBs.

The present invention thus provides a continuous process for manufacture of a low energy loss, multi-layered product useful for printed circuit boards or antenna boards, said process comprising the steps of.
a) providing metal foil;
b) optionally, extrusion coating molten polypropylene upon said metal foil, to obtain a foil coated with a polypropylene foundation layer;
c) casting a molten polypropylene tie-layer upon said metal foil or upon said coated metal foil;
d) laminating a polypropylene sheet on said tie-layer;
thereby forming a multi-layered product useful for further processing into a printed circuit board or an antenna board;
wherein in said process, fusing of the layers of said multi-layered product is induced by application of heat.

There is further provided a low energy loss, multi-layered product useful for manufacture of printed circuit boards or antenna boards, comprising:
a) a metal foil layer;
b) optionally, a polypropylene foundation layer upon said metal foil layer;
c) a polypropylene tie-layer upon said first polypropylene layer or upon said metal foil layer;
d) an additional polypropylene layer upon said polypropylene tie-layer.

### BRIEF DESCRIPTION OF THE DRAWINGS

For a better understanding of the invention with regard to the embodiments thereof, reference is made to the accompanying drawings, in which like numerals designate corresponding elements or sections throughout and in which:

FIG. 1 illustrates the first segment of a production line used to produce a multi-layered product useful for printed circuit boards or antenna boards, in accordance with the principles of the invention;

FIG. 2 illustrates the second segment of the production line used to produce the multi-layered product; and

FIG. 3 is a cross-sectional view of a double clad multi-layered polypropylene-metal foil product according to the invention, which can be etched to create a printed circuit board.

### DETAILED DESCRIPTION OF THE INVENTION

It is important to note that the process of the invention is a continuous process, allowing circuit boards to be produced on an automated production line in a roll-to-roll manner. The speed of the continuous process is relatively high, and thus cost efficient compared to prior art processes, and the process allows production of 50-150 meters of multi-layered product for each minute of operation of the production process.

FIG. 1 illustrates the first segment of the production line used to produce the multi-layered product. Referring to FIG. 1, conductive metal foil, for instance electrodeposited copper foil, is unwound in an unwinding station (10). Preferably, as a first step in the process of the invention, the conductive metal foil is primed at a priming station (100), to increase its adhesive properties. The conductive foil is primed with a material such as R-1559 (produced by Mica Corp., Shelton, Conn.) which is an aqueous primer comprising polypropylene (PP) molecules and acid. A gravure roller is partially immersed in a primer bath (20) that comprises priming station (100), and liquid primer is passed upon the roller surface onto the foil.

The foil is then placed in an oven (30) at a temperature within the range of 150 to 220° C., most preferably 180 to 210° C., for 2 to 15 sec. to induce drying and fusing of the primer with the metal foil. A coating of primer, at a thickness of approximately 0.05 to 0.5 microns, when dry, will thus be formed upon the porous side of the metal foil. This primer coating, in its dried and fused form, is non-polar.

Next, in an optional step, a foundation layer of molten polypropylene is preferably extruded upon the primed foil, in a continuous process comprising extrusion coating and lamination using an extruder (50) with a slot die (40) at a temperature within the range of 200-340° C., to deposit a thin layer of approximately 5 to 70 microns, most preferably 12-50 microns. The foil product passes between pressure roller (60) and a chill roller (70) having a chilled core, which causes the layer to cool almost instantaneously. Pressure roller (60) assures uniformity of product. The foil is rewound on rewinding station (80).

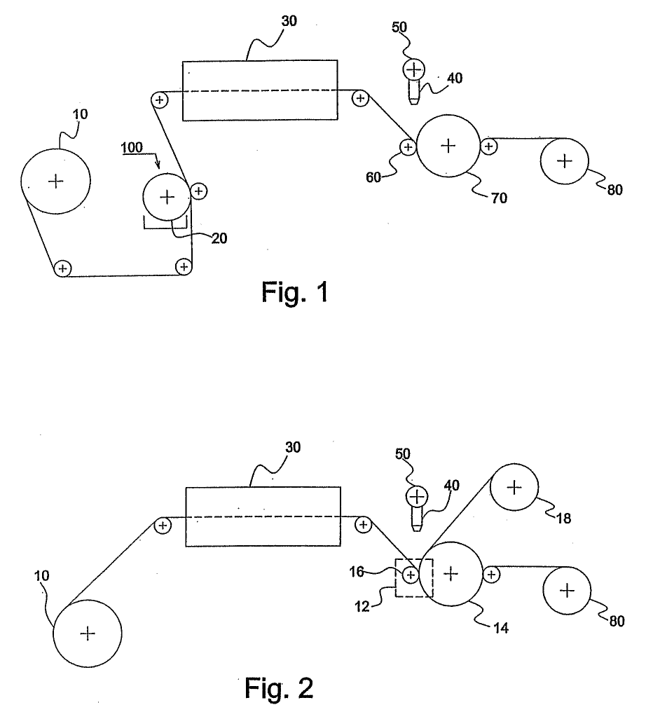

In order to ensure fusing of the layers of the final multi-layered product, and prevent peeling of the polypropylene off of the metal foil, it has presently been found in accordance with the invention that heat must be applied to the product. The necessary heat can be delivered as part of the inventive continuous process in one of several ways:
1. By admixing filler having a high density ceramic powder content into the polypropylene resin used to form the molten polypropylene foundation layer. The ceramic powder, preferably titanium dioxide or silica, when present at a high enough concentration, retains heat due to its density, and ensures fusing of the molten polypropylene to the metal foil. The ceramic powder additionally increases the melting point of the polypropylene resin. Preferably, the ceramic powder is present at a concentration of 1% to 60% by weight.
2. By curing the polypropylene-coated metal foil:
Referring to FIG. 2, the coated metal foil is unwound at unwinding station (10), and cured in an oven (30) at a temperature of approximately 150-220° C., most preferably 180-210° C., for a period of 2 to 15 seconds, most preferably 3-7 seconds, allowing fusing of the foundation layer with the primer (or with the unprimed metal foil). The brief oven-curing has been found to considerably increase the adhesion of the polypropylene to the metal foil, and to significantly raise the “peel strength” (strength required to peel off a layer) of the polypropylene. Prolonging the extent of the curing has been found to adversely influence the results, and prevent adhesion of additional layers.
3. By heating the surrounding work area (termed the “nip area”) during the step of casting a molten “tie-layer”, described hereinbelow. The temperature of the work area is raised above ambient temperature (above 25° C., preferably to a temperature of 45-90° C.).
   One or more of these options for delivery of heat may be utilized to ensure fusing of the polypropylene layers in the multi-layered product.

Referring again to FIG. 2, in a further step of the process, a molten cast “tie-layer” of polypropylene is applied; this is preferably performed using extrusion lamination machinery such as a slot die (40) extruder (50). Optionally, this is performed in a heated area (12) (termed the “nip area”), to ensure fusing of the layers in the multi-layered product.

Then a polypropylene sheet, having a thickness in the range of 25-2000 microns or more, most preferably in the range of 50 micron to 750 micron, is unwound from an unwinding station (18) and laminated upon the tie-layer using compression between rollers (16), (14) as the next step of the continuous process. The multi-layered product is rewound on a rewinding station (80).

The resulting multi-layered product may be designated for use as a single-clad product for processing into a PCB or an antenna board. When a single-clad product is required, a thicker polypropylene sheet is used, having for instance, a thickness of 200 to 2000 microns.

Alternatively, the resulting single side copper clad material may be used to create double sided copper clad laminate of double-thickness metal foil/polypropylene boards (also termed a “double clad product”). In such case, an additional polypropylene tie-layer is used between the two products, to laminate them to a single board. This tie-layer should have a thickness of approximately 5 to 100 microns, more preferably 5-70 microns, most preferably 15-60 microns. The double-clad product is formed using the production line described in FIG. 2, however the oven (30) is bypassed.

In one embodiment, the second product used to create the double-clad product, contains only a metal foil layer and a foundation layer.

The product thus formed is now a multi-layered polypropylene-metal foil product, which can then be etched, to create a circuit pattern, creating a printed circuit board or, in particular, an antenna board.

The metal foil is preferably selected from (but not limited to) one of the following materials: electrodeposited copper, rolled copper, rolled aluminum, gold and gold plated copper or aluminum and tin plated aluminum. Combinations and sub-combinations of multi-layered foils are possible.

Optionally, any of the polypropylene layers may be loaded with additives and fillers, which modify the dielectric or mechanical properties, or provide fire retardation, or promote cross-linking of the polymers.

Examples of cross-linking additives are: Triallyl Isocyanurate (TAIC)—0.1 to 6% by weight; Triallyl Cyanurate (TAC)—0.1 to 6% by weight; Trimethyrolpropanemethacrylate (TMPTMA)—1 to 10% by weight. These, or other cross-linking additives, may additionally act as fire retardants.

Examples of fire retardants are compounds containing borides, and specialty polypropylene fire-retardant additives.

Examples of compounds that alter the dielectric properties are ceramic powders such as titanium dioxide Rutile grade—5 to 60% by weight.

Examples of compounds that prevent shrinkage or thermal expansion are ceramic powders like silica, at a concentration of 5 to 50% by weight and titanium dioxide Anatase grade, at a concentration of 5 to 50% by weight.

Optionally, the final laminate may be irradiated using either beta or gamma energy to promote cross-linking, as described in EP 1160077, after application of additives that promote the cross-linking. The irradiation step may be performed in a continuous or a batch process.

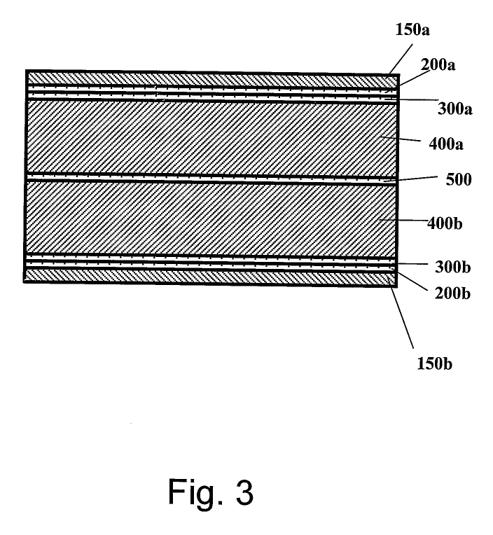

FIG. 3 illustrates corss-sectional view of a double clad multi-layered polypropylene-metal foil product in accordance with the invention. The product can be etched to create a printed circuit board or, for instance, an antenna board. The outermost layers (150a, 150b) are metal foil, such as copper. Layers (200a, 200b) are formed of molten polypropylene, and each such layer represents a foundation layer. Layers (300a, 300b) are formed of molten polypropylene, and each such layer represents a tie-layer. Layers (400a, 400b) are formed of polypropylene sheets, each having a thickness in the range of 25-1000 microns or more, laminated upon the tie-layer. Layer (500) is a second tie-layer, formed of molten polypropylene, which binds the product into a double-clad product. The double-clad product can then be etched, to create a circuit pattern for a printed circuit board or an antenna board.

Having described the invention with regard to certain specific embodiments thereof, it is to be understood that the description is not meant as a limitation, as further modifications will now become apparent to those skilled in the art, and it is intended to cover such modifications as are within the scope of the appended claims.

1. A continuous process for manufacture of a low energy loss, multi-layered product useful for printed circuit boards and for antenna boards, said process comprising the steps of:
a) providing metal foil;
b) optionally, extrusion coating molten polypropylene upon said metal foil, to obtain a foil coated with a polypropylene foundation layer;
c) casting a molten polypropylene tie-layer upon said metal foil or upon said coated metal foil; and
d) laminating a polypropylene sheet on said tie-layer;
thereby forming a multi-layered product useful for further processing into a printed circuit board or an antenna board,
wherein in said process, sufficient heat is applied to induce fusing of the layers of said multi-layered product.

2. The continuous process of claim 1, wherein said application of heat for inducing fusing of said layers, comprises curing said coated metal foil by placement in an oven at a temperature of 150-220° C. for several seconds; said curing step is performed between steps (b) and (c).

3. The continuous process of claim 1, wherein said application of heat for inducing fusing of said layers, comprises adding a ceramic powder to said molten polypropylene, for extrusion coating in step (b).

4. The continuous process of claim 3, wherein said ceramic powder is selected from titanium dioxide or silica, provided at a concentration within the range of 1% to 60%.

5. The continuous process of claim 1, wherein said application of heat for inducing fusing of said layers, comprises performing step (c) at a surrounding temperature higher than 25° C.

6. The continuous process of claim 5, wherein said surrounding temperature is within the range of 45 to 90° C.

7. The continuous process of claim 1, further comprising the following steps, performed before said step of extrusion coating with molten polypropylene:
a) priming said metal foil by passing the metal foil over a gravure roller partially immersed in a primer bath, said primer bath comprising a primer of aqueous polypropylene and acid;
b) curing said metal foil in an oven at a temperature within the range of 150-220° C. for several seconds.

8. The continuous process of claim 1 wherein said metal foil is comprised of at least one layer of metal selected from the following materials: electrodeposited copper, rolled copper, rolled aluminum, gold, gold plated copper or gold plated aluminum and tin plated aluminum.

9. The continuous process of claim 1, wherein at least one of said foundation layer of step (b) and said polypropylene tie-layer used in step (c), have a thickness in the range of 5-70 microns.

10. The continuous process of claim 1, wherein said polypropylene sheet used for lamination in step (d) has a thickness in the range of 25 to 2000 microns, and wherein said multi-layered product formed in claim 1 is laminated to a second multi-layered product to form a double clad product.

11. The continuous process of claim 10, wherein said second product is produced using only steps (a) and (b) of the process of claim 1.

12. The continuous process of claim 1, wherein said polypropylene used in any of steps (b), (c) or (d), additionally comprises additives selected from: additives that modify the dielectric properties, additives that modify the mechanical properties, fire retardants or cross-linking promotion additives.

13. The continuous process of claim 1, further comprising the final step of irradiating the product using beta or gamma rays for promoting cross-linking.

14. A low energy loss, multi-layered product useful for manufacture of printed circuit boards or antenna boards, comprising:
a) a metal foil layer;
b) optionally, a polypropylene foundation layer upon said metal foil layer;
c) a polypropylene tie-layer upon said first polypropylene layer or upon said metal foil layer; and
d) an additional polypropylene layer upon said polypropylene tie-layer.

15. The product of claim 14, further comprising a polypropylene primer layer having a thickness within the range of 0.1-1.0 micron, said layer present upon said metal foil layer.

16. The product of claim 14, wherein at least one of said polypropylene foundation layer (b) or said polypropylene tie-layer (c), has a thickness in the range of 5 to 70 microns.

17. The product of claim 14, further comprising a second multi-layered product, laminated to the polypropylene tie-layer to form a double clad product.

18. The product of claim 17, wherein said second multi-layered product comprises a metal foil layer and a single polypropylene layer.

19. The product of claim 14, wherein said additional polypropylene layer (d) has a thickness in the range of 25 to 2000 microns.

20. The product of claim 14, wherein said metal foil is comprised of at least one layer of metal selected from the following materials: electrodeposited copper, rolled copper, rolled aluminum, gold, gold plated copper and gold or tin plated aluminum.

21. The product of claim 14, wherein said polypropylene layers contain additives selected from: additives that modify the dielectric properties, additives that modify the mechanical properties, fire retardants and cross-linking promotion additives.

22. The product according to claim 21, wherein said cross-linking promotion additives are selected from: triallyl isocyanurate, triallyl cyanurate, and trimethyrolpropane-methacrylate.

23. The product according to claim 21, wherein said fire retardant is selected from: a compound containing boride, a modified polypropylene additive, and triallyl isocyanurate, triallyl cyanurate, and trimethyrolpropane-methacrylate.

24. The product according to claim 21, wherein said additive that modifies the dielectric properties is titanium dioxide Rutile grade, present at 5 to 60% by weight.

25. The product according to claim 21, wherein the additives that modify the mechanical properties are ceramic powders selected from: titanium dioxide Anotase grade and silica.

26. The product of claim 14, wherein said polypropylene foundation layer includes filler having a ceramic powder content admixed in said layer.

27. The product of claim 26, wherein said ceramic powder is selected from titanium dioxide and silica, present at a concentration in the range of 1% to 60%.
